(19) United States
(12) Patent Application Publication
(10) Pub. No.: US 2026/0268056 A1
(43) Pub. Date: Sep. 10, 2026

(54) PATTERN MATCHING IDENTIFICATION OF DESIGN LAYOUTS

(71) Applicant: Taiwan Semiconductor Manufacturing Company, Ltd., Hsinchu (TW)

(72) Inventors: Ming-Yu YEH, Hsinchu (TW); Hui-Hua SHIH, Hsinchu (TW); Huang-Sheng LIN, Hsinchu (TW); Ying-Hsiu KUO, Hsinchu (TW); Kang-Yu HSU, Hsinchu (TW); Jui-Wen CHANG, Hsinchu (TW); Feng-Ming CHANG, Hsinchu (TW)

(73) Assignee: Taiwan Semiconductor Manufacturing Company, Ltd., Hsinchu (TW)

(21) Appl. No.: 19/073,338

(22) Filed: Mar. 7, 2025

(51) Int. Cl. G06F 30/392; G06F 30/327

(52) U.S. Cl. CPC G06F 30/392; G06F 30/327

(57) ABSTRACT

A method of generating a pattern match identifier (PMID) includes receiving a first cell layout design, the first cell layout design having one or more layers; generating a PMID for the first cell layout design using a predefined encoding, the PMID based on an attribute of the first cell layout design; and generating a second cell layout design based on the first cell layout design and the PMID, the PMID being stored in a layer of the second cell layout design.

### BACKGROUND

Circuit design for integrated circuits has become increasingly complex, with designers relying heavily on pre-designed templates to create various circuit components and structures. These templates, which include standard cells, memory structures, and other circuit elements, are tools that enhance design efficiency and reliability.

Current design verification tools identify various types of design rule violations and potential manufacturing defects through simulation and analysis. Furthermore, multiple designers may use and modify the same templates across different projects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor device layout, in accordance with some embodiments.

FIG. 2 is a flowchart of a method of generating and embedding a PMID in a cell layout template, in accordance with some embodiments.

FIG. 3 is a plan view of an example cell layout template, in accordance with some embodiments.

FIG. 4 is a cross-section view of a portion of the cell layout template of FIG. 3.

FIG. 5 is a plan view of an identifier layer of a memory cell template, in accordance with some embodiments.

FIGS. 6A-J are plan views of identifier layers of a memory cell template, in accordance with some embodiments.

FIG. 7 is a flowchart of another example encoding method, in accordance with some embodiments.

FIG. 8 is a name of a memory cell template, in accordance with some embodiments.

FIG. 9 is a table of mapping characters to reference numbers, in accordance with some embodiments.

FIG. 10 is an encoded version of the FIG. 8 name, in accordance with some embodiments.

FIG. 11 is a flowchart of a method of generating an identifier, in accordance with some embodiments.

FIG. 12 is a flowchart of a method of updating a software tool with an identifier, in accordance with some embodiments.

FIG. 13 is a flow chart of a method of executing a pattern match using an identifier, in accordance with some embodiments.

FIG. 14 is a block diagram of an integrated circuit (IC) manufacturing system, and an IC manufacturing flow associated therewith, in accordance with some embodiments.

FIG. 15 is a flowchart of a method of manufacturing a semiconductor device, in accordance with some embodiments.

FIG. 16 is a block diagram of an electronic design automation (EDA) system, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more embodiments disclose a system and method for embedding and tracking unique identifiers within layout design templates while maintaining template functionality and enabling efficient template identification during design verification processes. The one or more embodiments accomplish this by using a dedicated layer within the multi-layer structure of integrated circuit designs, separate from functional layers such as metal, insulator, and interconnect layers.

In one aspect, the embodiments include a method for generating unique identifiers for layout design templates using a generation process that considers various inputs while maintaining identifier uniqueness. The generated identifier is embedded within a dedicated layer of the template, ensuring no interference with the template's circuit functionality.

In another aspect, the one or more embodiments disclose an automated system for detecting and decoding template identifiers during design verification, enabling quick identification of template sources if design issues are discovered. The system includes capabilities for template comparison, highlighting differences between original and modified templates.

The one or more embodiments further include features for template identification and tracking.

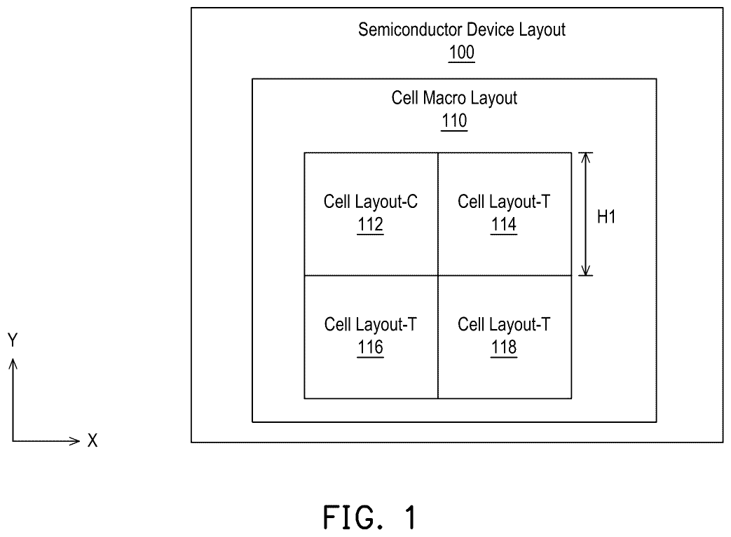

In FIG. 1, a semiconductor device layout 100 includes, among other things, at least one cell macro layout 110. A layout designer generates a layout, such as semiconductor device layout 100, to form an integrated circuit design layout diagram. The generation of the layout includes one or more of logic design, physical design, and/or place and route. Layout 100 is presented in one or more data files having information of geometrical patterns on multiple layers which when implemented form the circuit design. For example, layout 100 can be expressed in a GDSII file format or a DFII file format.

In some embodiments, cell macro layout 110 corresponds to a set of semiconductor components configured as a memory, a controller, one or more logic gates, or the like. Cell macro layout 110 includes, among other things, one or more cell layouts, such as cell layout 112, cell layout 114, cell layout 116, and a cell layout 118. In some embodiments, each one of cell layouts 112, 114, 116, 118 include layout patterns indicative of transistors or other components to be formed based on one or more active regions extending along a first direction (e.g., the X direction) and one or more gate structures extending along a second direction (e.g., the Y direction).

In some embodiments, each one of the layout cells of cells 112, 114, 116, and 118 includes layout patterns indicative of respective conductive lines within one or more metallization layers and electrically connecting various transistors or other components of cells 112, 114, 116, and 118. In some embodiments, the semiconductor device layout 100 defines multiple power track regions extending along the first direction configured to carry a first supply voltage (e.g., VDD) or a second supply voltage (e.g., VSS or ground). In some embodiments, a cell layout includes a first side extending along a power track region and a second side extending along another power track region. In some embodiments, a cell layout that does not have any other power track region between the first side and the second side thereof is sometimes referred to as having a standard cell height. In some embodiments for a more compact design based on some processing nodes, a cell layout having a standard cell height includes up to four or five metallization regions (other than the power track regions) extending along the first direction in a lowest metallization layer (also referred to as MO layer) over the transistors of the cell. In some embodiments, any of cell height H1, H2, and H3 has a standard cell height (e.g., a 1H cell), two standard cell heights (e.g., a 2H cell), or three standard cell heights (e.g., a 3H cell). In some embodiments, a cell layout in cell macro layout 110 corresponds to multiple standard cell heights or less than one standard cell height (e.g., a ½H cell).

Layout designers use electronic design automation tools, such as VIRTUOSO® available from CADENCE DESIGN SYSTEMS, Inc., or another suitable layout generating tool, to generate layouts. Layout designers design cell layouts as new cells or based on existing cell layout templates. The cell layout templates are from the design house, a mask house, a fab, or the software tool vendor. Semiconductor device layout 100 includes one or more cell macro layouts 110 which further include one or more cell layouts such as cell layouts 112-118. Cell layout-C 112 is a custom or new cell layout designed by a layout designer. Cell layout-T 114-118 are cell layouts based on cell layout templates used by the layout designer. The layout designer uses cell layout templates for a variety of reasons including increasing efficiency of production of semiconductor device layout 100.

If an issue or error arises during layout simulation or validation related to a cell layout template, efficient identification of the cell layout template forming the basis for the cell layout template used by the designer improves the speed of identifying and/or correcting the issue or error. In other approaches, a time-consuming comparison of cell layout templates with the cell layout at issue is performed to identify the corresponding cell layout template. In at least some approaches, an image comparison of the cell layout templates and cell layout at issue is performed. Given the density, complexity, and number of layers to be compared, such approaches are compute-intensive and time-intensive.

In an embodiment of the present disclosure, each unique cell layout template 112-118 is configured to include a unique pattern match identifier (PMID) embedded in the layout. The PMID is generated based on at least one attribute of the layout. In at least some embodiments, the PMID is embedded in a separate layer of the cell layout template. Embedding the PMID in a separate layer prevents the PMID from impacting any component or circuit in the remaining layer of the cell layout. In at least some embodiments, the PMID is embedded in the top-most layer of the cell layout template. Embedding the PMID in the top-most layer improves the visibility of the PMID for manual and/or automated processes of reading the PMID from the cell layout template.

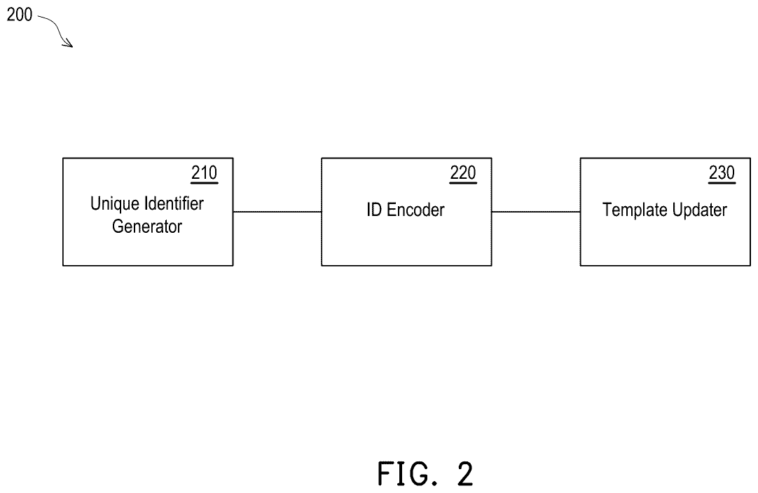

FIG. 2 is a flowchart of a method 200 of generating and embedding a PMID in a cell layout template. At process 210, a unique identifier of the cell layout template is generated. In at least one embodiment, the unique identifier is generated automatically. In at least one embodiment, the unique identifier is generated manually. The unique identifier is unique among the cell layout templates. The unique identifier corresponds to at most one cell layout template.

In at least one embodiment, the unique identifier is a name of the cell layout. In at least one embodiment, the unique identifier is a serial number of the cell layout. In at least one embodiment, the unique identifier is a combination of a name and a serial number of the cell layout. In at least one embodiment, a data store such as a database stores all the unique identifiers of the cell layouts. In at least one embodiment, each generated unique identifier is checked against the unique identifiers in the data store to confirm uniqueness.

The flow proceeds to process 220. At process 220, the unique identifier is encoded to form a pattern match identifier (PMID). In at least one embodiment, the encoding comprises one or more of a mapping table, a Quick Response (QR) encoder, a barcode encoder, a hashing function, or a text formatter.

In at least one embodiment, the encoding generates a PMID comprising an array of markers corresponding to the encoded unique identifier. In at least one embodiment, the markers are at least one of circles, polygons, rectangles, or the like. In at least one embodiment, the encoding generates a PMID comprising at least one of a QR code or a barcode. In at least one embodiment, the encoding generates a set of characters. In at least one embodiment, the encoding generates a PMID comprising a combination of an array of markers and a set of characters.

The flow proceeds to process 230. At process 230, the generated PMID is embedded in a layer of the cell layout template, e.g., cell layout-T 112, as described above. In at least one embodiment, the PMID is embedded in a separate layer of the cell layout template. In at least one embodiment, the PMID is embedded in the top-most layer of the cell layout template. In at least one embodiment, a new cell layout template is created based on the cell layout template for which the PMID is generated and the PMID added to a new top-most layer of the cell layout template. In at least one embodiment, the cell layout template for which the PMID is generated is modified to include a new top-most layer comprising the generated PMID embedded therein.

In at least one embodiment, processes 210 and 220 are performed separate from process 230, i.e., at different times or by different entities. In at least one embodiment, process 230 is performed at the same time as creation of the cell layout template.

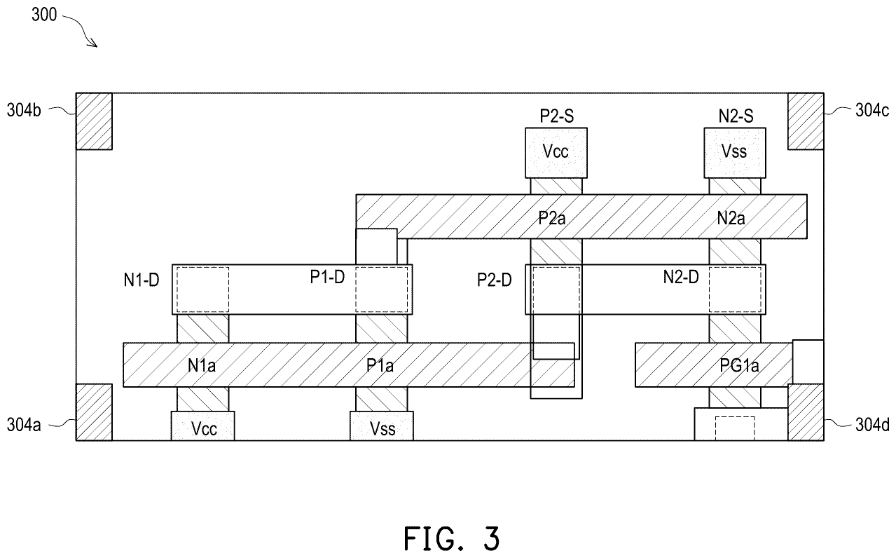

FIG. 3 is a plan view of an example cell layout template 300, in accordance with some embodiments. FIG. 3 is a static random access memory (SRAM) memory cell layout template. In at least some embodiments, cell layout template is another component cell layout. An EDA tool is used to display the cell layout template to a designer at a design house, e.g., design house 1402, using a user interface. The cell layout template 300 is used in the creation of an IC design layout diagram, e.g., IC design layout diagram 1422. In at least some embodiments, cell layout template 300 is provided by a fab, e.g., fab 1406, to enable designers to reuse existing cell layouts. In some embodiments, the cell layout template 300 is a template provided by the EDA tool vendor. In some embodiments, the cell layout template 300 is a template provided by a mask house, e.g., mask house 1404.

Cell layout template 300 comprises a graphical depiction of various elements that make up a cell, e.g., an SRAM memory cell including N-wells, P-wells, metal lines, via connections, and the like. Different memory cell arrangements and types are contemplated. In some embodiments, layout template 300 comprises a single memory cell. In some embodiments, layout template 300 comprises a different type of cell. In some embodiments, layout template 300 comprises a functional cell. In some embodiments, cell macro layout 110 comprises hundreds, thousands, or millions of cell layouts thereby increasing the importance of being able to easily and rapidly identify a particular cell layout template when used. In some embodiments, semiconductor device layout 100 comprises hundreds, thousands, or millions of cell macro layouts 110 further increasing the importance of being able to easily and rapidly identify a particular cell layout template being used.

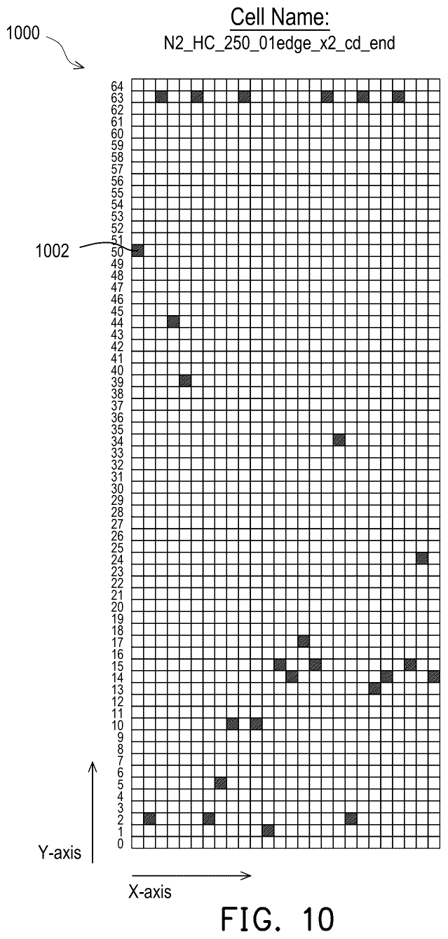

Cell layout template 300 comprises a pattern matching identifier (PMID) 304 in each corner of the cell. PMID 304, in accordance with at least one embodiment, is described in more detail below with respect to FIG. 10. PMID 304a is in a lower left corner, PMID 304b is in an upper left corner, PMID 304c is in an upper left corner, and PMID 304d is in a lower right corner. Hereafter, PMID 304 is used to reference a single PMID and attributes of the PMID.

In at least some embodiments, layout template 300 comprises a single PMID 300. In at least some embodiments, layout template 300 comprises greater or lesser numbers of PMIDs. In at least some embodiments, layout template 300 comprises PMIDs positioned in different locations. In at least one embodiment, layout template 300 comprises a single PMID 304 in the center of layout template 300. In at least one embodiment, layout template 300 comprises a single PMID 304 along an upper, lower, left, or right edge and between corresponding corners of the edge.

Further variations of positions and numbers of PMIDs on a layout template are described with reference to FIGS. CC11A-J. In at least one embodiment, the PMID arrangement is one of FIGS. CC11A-J, a variation on one of FIGS. CC11A-J, or a combination of one or more of FIGS. CC11A-J.

In at least some embodiments, PMID 304 is positioned in cell layout template 300 to avoid or minimize obscuring the plan view of the cell layout template. In at least some embodiments, each PMID 304 covers a larger or smaller area of the cell.

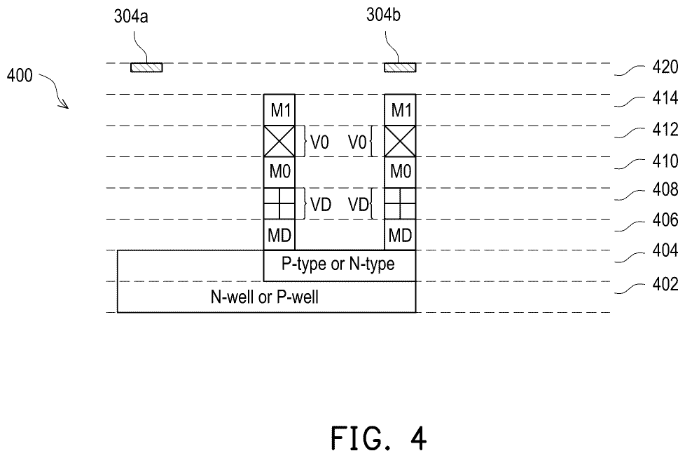

FIG. 4 is a cross-section view of a portion 400 of the SRAM memory cell layout template 300 of FIG. 3. Cross-section portion 400 corresponds to section line A-A of FIG. 3. Layout template 300 comprises multiple layers making up the SRAM memory cell template. In at least some embodiments, greater or lesser numbers of layers make up cross-section portion 400. Each layer contains different elements for the SRAM memory cell layout. The multiple layers are stacked one upon another. One or more layers are used for P-type or N-type wells, metal routing lines, via connections, or the like. FIG. 4 includes layers 402-420 making up the portion 400 of template 300.

PMIDs 304a and 304b are located in upper-most layer 420 (also referred to as PMID layer 420) of layers 402-420 of the portion 400. In at least some embodiments, PMID layer 420 is a bottom-most layer of layers 402-420. In at least some embodiments, PMID layer 420 is an intermediate layer of layers 402-420.

PMID layer 420 is implemented as a distinct layer within the structure of template 300, separate from the layers that define the electrical and physical characteristics of the circuit embodied in the template. The separation ensures that the presence of the identifier does not affect the electrical properties, timing characteristics, or manufacturing parameters of the circuit design.

By positioning PMID layer 420 above all functional layers in the stack of layers 402-420, the PMID layer is accessible for identifier reading and verification, there is minimal to no risk of interference with circuit functionality, there is a reduced likelihood of accidental modification of the identifier during template editing compared to other approaches, and there is a clear separation from manufacturing-critical layers.

In at least one embodiment, the dimensions of the PMID 304 vary depending on the content of the PMID. In at least one embodiment, the dimensions of the PMIDs 304 are adjusted in order to prevent overlap of the PMIDs on the PMID layer 420. In at least one embodiment, the EDA tool is configured to not display PMID layer 420 to the user, e.g., a layout designer. In at least one embodiment, the EDA tool is selectively configurable to display PMID layer 420 or not to the user.

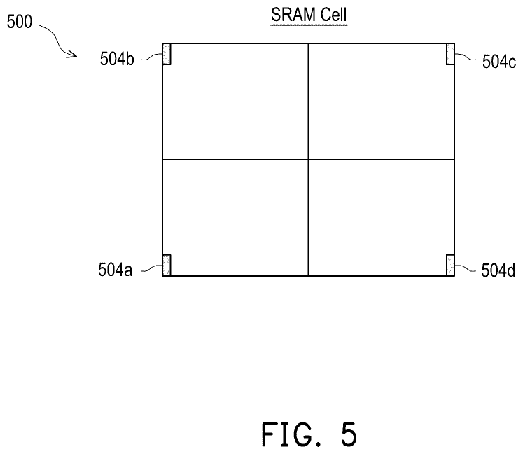

FIG. 5 is a plan view of an example identifier layer 500, similar to PMID layer 420, of a memory cell template, e.g., SRAM memory cell template 300 (FIG. 3), in accordance with some embodiments. FIG. 5 is similar to FIG. 3 with the design layers, e.g., cross-section layers 402-414 (FIG. 4), removed or hidden from view. PMID layer 500 includes PMIDs 504 arranged at four corners of the cell template, i.e., PMID 504a, 504b, 504c, and 504d.

PMID 504a is in a lower left corner, PMID 504b is in an upper left corner, PMID 504c is in an upper left corner, and PMID 504d is in a lower right corner. PMID 504b is a mirror image of PMID 504a about a horizontal axis. PMID 504d is a mirror image of PMID 504a about a vertical axis. PMID 504c is a mirror image of PMID 504a about a horizontal axis and a vertical axis.

In at least some embodiments, PMIDs 504a-d are all oriented in the same direction. In at least some embodiments, PMIDs 504a-d are each oriented in a different direction with respect to the other PMIDs 504a-d. Orienting PMIDs 504a-d in different directions improves the readability of at least one PMID.

In at least some embodiments, layer 500 comprises a single PMID 504. In at least some embodiments, layer 500 comprises greater or lesser numbers of PMIDs. In at least some embodiments, layer 500 comprises PMIDs positioned in different locations. In at least one embodiment, layer 500 comprises a single PMID 504 in the center of the layer. In at least one embodiment, layer 500 comprises a single PMID 504 along an upper, lower, left, or right edge and between corresponding corners of the edge. In at least some embodiments, PMID 504 is offset or shifted from one or more edges or corners of layer 500.

In at least some embodiments, PMID 504 is positioned in cell layer 500 to avoid or minimize obscuring the plan view of the cell layout template. In at least some embodiments, each PMID 504 covers a larger or smaller area of the layer.

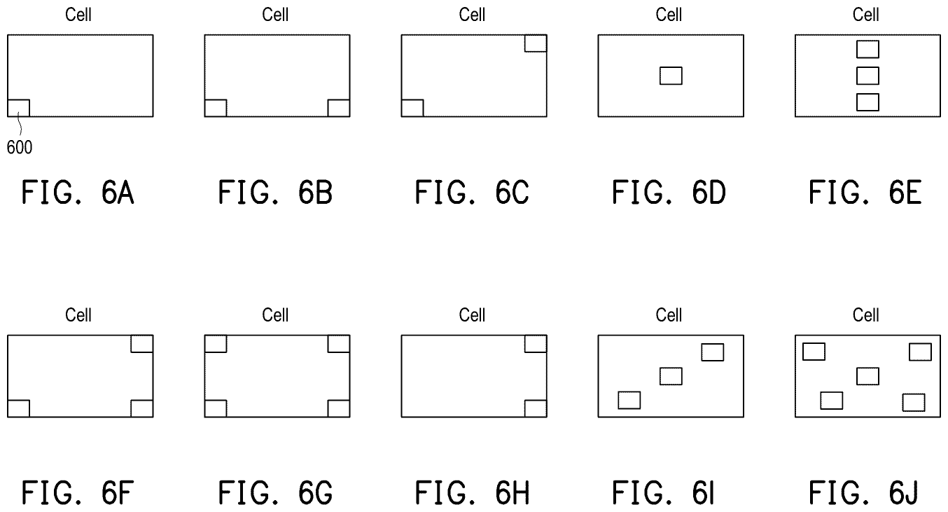

FIGS. 6A-J are plan views of identifier layers, e.g., PMID layer 420, 500, of a memory cell template, e.g., SRAM memory cell layout template 300, in accordance with some embodiments. FIGS. 6A-J are non-limiting examples of different number and position of PMIDs 600 on a given identifier layer.

FIG. 6A includes a single representative PMID 600 at a lower left corner of the identifier (PMID) layer. FIG. 6B includes two PMIDs 600; one PMID at the lower left corner and one PMID at the lower right corner. FIG. 6C includes two PMIDs 600; one PMID at the lower left corner and one PMID at the upper right corner. FIG. 6D includes a single PMID 600 in the center of the memory cell template.

FIG. 6E includes three PMIDs 600 vertically aligned and equidistant from the top to bottom of the memory cell template. FIG. 6F includes three PMIDs 600; one PMID at each of three of the four corners of the memory cell template. FIG. 6G includes four PMIDs 600; one PMID at each of the four corners of the memory cell template. FIG. 6H includes two PMIDs 600 similar to FIG. 6B, except instead of having a PMID at the lower left corner, the other PMID is at the upper right corner of the memory cell template.

FIG. 6I includes three PMIDs 600 similar to FIG. 6E, except the three PMIDs are arranged diagonally equidistantly across the memory cell template from the lower left corner to the upper right corner. FIG. 6J includes five PMIDs 600 randomly distributed around the memory cell template.

In at least some embodiments, PMID 600 (or multiple PMIDs) is locatable anywhere within the boundary of the cell template. In at least some embodiments, PMID 600 (or multiple PMIDs) is limited to the locations or arrangements specified by one or more of the embodiments of FIGS. 6A-J.

In at least some embodiments, PMID 600 is offset by a predefined distance value from one or more of a corner, an edge, a center, or the like of the cell template.

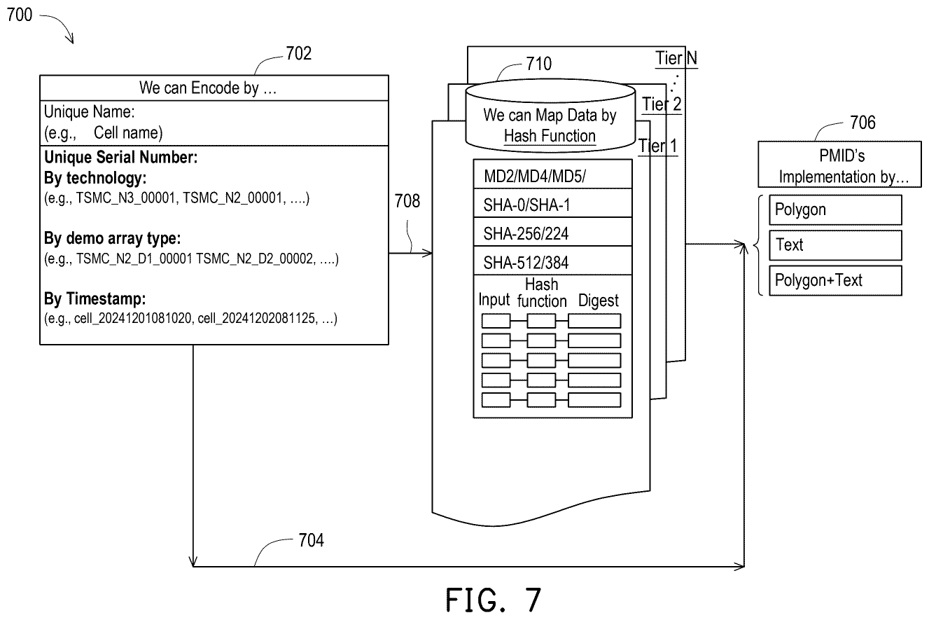

FIG. 7 is a flowchart of another example encoding method 700, in accordance with some embodiments. Method 700 begins at process 702. Process 702 is also referenced as a template identifier generator, e.g., unique identifier generator 210. Execution of process 702 by a computer system, e.g., EDA system 1600, causes an identifier of a particular memory cell layout to be uniquely determined. In at least one embodiment, the cell identifier, e.g., cell template name 800, is a unique identifier comprising multiple characters. In at least some embodiments, a data store, e.g., in memory 1604, stores the encoded cell identifiers for other cell layout templates and EDA system 1600 compares a new cell identifier with existing stored identifiers to ensure uniqueness.

In at least one embodiment, the cell identifier is a unique serial number assigned incrementally or sequentially. In at least one embodiment, the unique serial number comprises letters, numbers, or other typographical symbols. In at least one embodiment, the cell identifier includes one or more characters identifying a technology node of the memory cell layout. For example, “N3” corresponding to a N3 node level, “N2” corresponding to an N2 node level, and the like. In at least one embodiment, the cell identifier includes one or more characters identifying a demonstration array type of the memory cell layout. For example, “D1” corresponding to a first demonstration array, “D2” corresponding to a second demonstration array, and the like.

In at least one embodiment, the cell identifier includes a time and/or date stamp corresponding to one of a creation or modification date of the memory cell layout. For example, “20241201081020” corresponding to a creation time of 8:10:20 on the date of Dec. 1, 2024, “20241202081125” corresponding to a creation time of 8:11:25 on the date of Dec. 2, 2024, and the like.

The flow proceeds to process 706 via path 704. Execution of process 706 by a computer system, e.g., EDA system 1600, causes the generation of a PMID, e.g., PMID 1000, for the memory cell layout. Process 706 is an embodiment of ID encoder 220. In at least one embodiment, process 706 encodes the cell identifier using a mapping table, e.g., mapping table 900, to generate the PMID, e.g., PMID 1000.

In at least one embodiment, process 706 encodes the cell identifier into a Quick Response (QR) code or barcode. In the QR code or barcode process, the cell identifier is encoded into a QR code or barcode using a standardized encoding algorithm, such as the Quick Response (QR) code standard or the Universal Product Code (UPC) standard. The encoding process translates the character string representing the cell identifier into a binary format, which is then divided into smaller chunks of data that are suitable for encoding in a QR code or barcode. The encoded data is then arranged in a specific pattern to form the actual QR code or barcode.

For example, when using a QR code, the encoded cell identifier would be divided into 8-bit segments, with each segment representing one byte of data. These segments are arranged in a specific matrix format, with each row and column representing one bit of data. The resulting QR code contains a series of black and white squares that correspond to the binary data used to encode the cell identifier.

Alternatively, if a barcode is chosen, the encoding process uses a different algorithm, such as the UPC or European Article Number (EAN) standard. In this case, the encoded cell identifier is divided into smaller chunks of data, which are then arranged in a specific pattern to form the actual barcode. The resulting barcode consists of a series of parallel lines or other shapes that correspond to the binary data used to encode the cell identifier.

In at least one embodiment, process 706 encodes the cell identifier into a text format comprising a string of characters representing the cell identifier. In at least one embodiment, the string of characters corresponds to the characters of either the unique cell name, the unique serial number, or a combination of both.

In at least one embodiment, the encoded cell identifier comprises more than one set of text. For example, in an embodiment the encoded cell identifier comprises an encoded version of the unique cell name and an encoded version of a unique serial number. In the given example, the two sets of text are positioned one above the other. In an embodiment, the two sets of text are concatenated.

In at least one embodiment, process 706 encodes the cell identifier into a combination of two or more of PMID 1000, a QR code or barcode, or a text format. In at least one embodiment, process 706 encodes the cell identifier into a combination of all three of PMID 1000, a QR code or barcode, and a text format.

Depending on configuration, process 702 proceeds to an optional process 710 via path 706. Execution of process 710 by a computer system, e.g., EDA system 1600, causes an additional hashing process to be performed before proceeding to process 706. Process 710 performs a hashing function on the cell identifier, e.g., unique cell name or unique serial number from process 702, to generate a unique set of values for use by process 706 to generate the PMID. In at least one embodiment, the cell identifier is the key for the hash function. In at least some embodiments, the hashing algorithm is MD2, MD4, MD5, SHA-0, SHA-1, SHA-224/256, SHA-384/512, or the like. The hashing function increases a difficulty of reverse engineering of the cell identifier from the PMID by a user.

In at least some embodiments, process 710 is executed more than once for a given cell identifier. In at least some embodiments, process 710 is executed with one or more additional keys for the hash function, e.g., time and/or date stamp of the layout template, size of the layout template, node of the layout template, or the like.

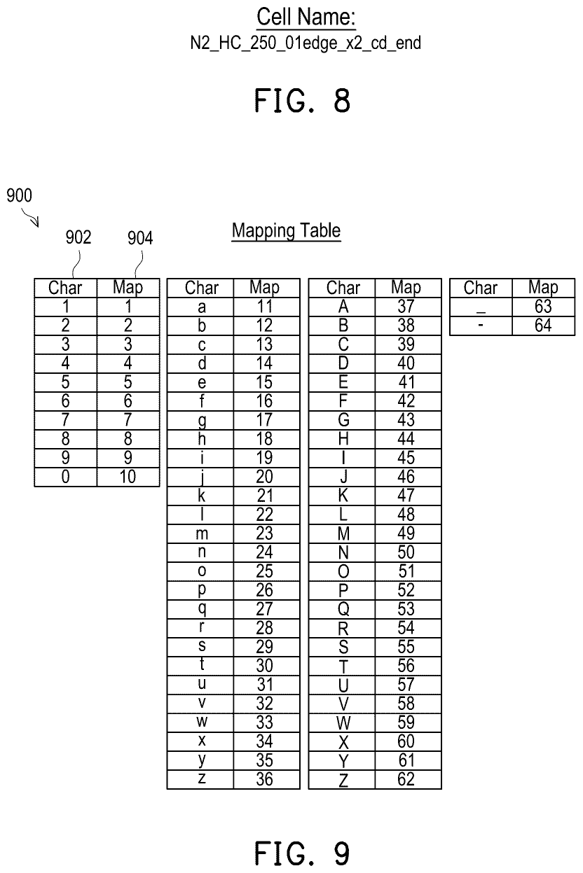

FIG. 8 is an example name of a memory cell template, e.g., SRAM memory cell layout 400 (FIG. 4), in accordance with some embodiments. Each cell template name 800 is unique. In at least one embodiment, the EDA tool enforces the requirement of cell template name 800 uniqueness by only allowing unique cell names for cell templates. In the example, a cell template name 800 is N2_HC_250_01edge_x2_cd_end. The first three characters, i.e., “N2_” of the cell name are used for the following explanation. In some embodiments, the cell template name uses greater or fewer numbers of characters.

FIG. 9 is a character mapping table 900 usable for mapping characters to reference numbers, in accordance with some embodiments. Table 900 is usable in conjunction with an embodiment of ID encoder 220. Table 900 includes two columns and multiple rows. Table 900 includes a character column 902 corresponding to the various characters usable in forming a cell name, e.g., cell template name 800. Character column 902 comprises all of the potential characters usable in a cell name. Table 900 includes a map column 904 corresponding to a unique reference number matched with a character in character column 902. Mapping table 900 is used as a lookup table for determining either a reference number from column 904 that matches with a given character or a character from column 902 that matches with a given reference number. Mapping table 900 is used to encode and/or decode a PMID on a given template, e.g., PMID 420.

In at least some embodiments, mapping table 900 comprises different encoding values. In at least some embodiments, map column 904 uses binary, octal, or hexadecimal values in place of decimal values.

Using the above example of the first three characters, “N2_”, mapping table 900 is used to determine that these characters map to reference numbers 50, 2, and 63 based on the values in map column 904. The remaining characters of cell template name 800 are encoded in the same manner.

FIG. 10 is an encoded version of the FIG. 8 name 800 in a PMID 1000, in accordance with some embodiments. PMID 1000 is a machine-readable label that contains data readable by a computer to provide the name of the cell layout template, e.g., layout template 300. PMID 1000 is an array (also referred to as a grid) of rows and columns in which the encoded version of the cell template name 800 is positioned. The array has an X axis and a Y axis; the Y axis being perpendicular to the X axis. The X axis has a number of columns corresponding to the number of characters in cell template name 800. In at least one embodiment, the number of columns in the X axis is fixed to a maximum cell template name 800 length. In at least one embodiment, a template updater applies PMID 1000 to a layer of the cell layout template.

The Y axis has a number of rows corresponding to the number of reference numbers in mapping table 900. In at least one embodiment, the number of rows in the Y axis is equal to the maximum value of the reference number in the encoded cell template name 800. For example, because cell template name 800 does not use a hyphen (“-”), the maximum value of the reference number in encoded cell template name 800 is 63 and the maximum number of rows in the Y axis is 63. In at least some embodiments, the X and Y axes are swapped such that the X axis is equal to the number of reference numbers in the mapping table 900 and the Y axis is equal to the number of characters in cell template name 800.

PMID 1000 includes a marker 1002 at the intersection of a row and column value corresponding to each encoded character of cell template name 800. In at least some embodiments, marker 1002 is a 1-unit size polygon where the unit depends on the node size of the layout template. In at least some embodiments, marker 1002 is larger or smaller than the 1-unit size. In at least some embodiments, the size of marker 1002 is adjusted based on the area of the cell layout template. In at least some embodiments, the size of marker 1002 is adjusted based on the number of PMIDs included on the cell layout template.

Marker 1002 is a polygon. In at least some embodiments, marker 1002 is a circular shape. In at least some embodiments, marker 1002 is a square. In at least some embodiments, marker 1002 is a rectangle. In at least some embodiments, marker 1002 is an ellipsoid.

In at least some embodiments, PMID 1000 includes only the markers positioned in an array without corresponding lines demarcating rows and/or columns.

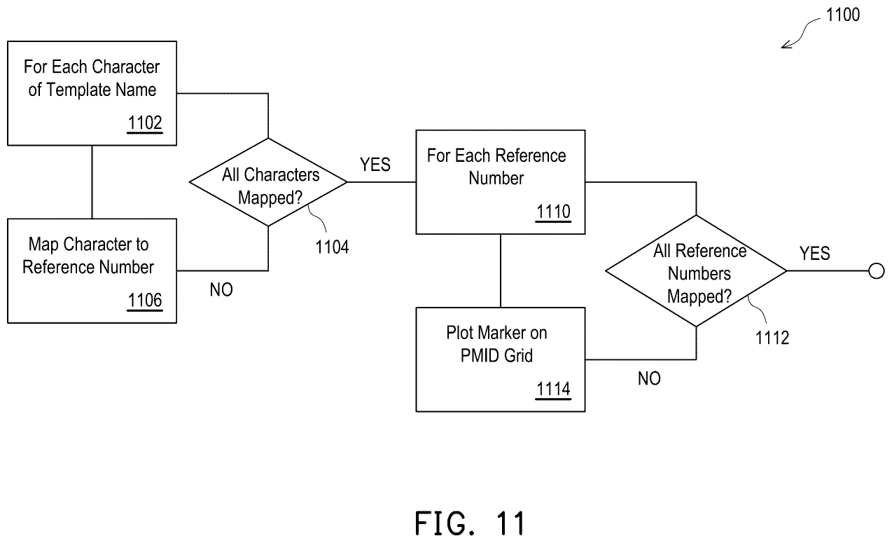

FIG. 11 is a flowchart of a method of generating an identifier 1100 corresponding to an embodiment of ID encoder 220, in accordance with some embodiments. Identifier (ID) generating method 1100 is described in connection with mapping table 900 and PMID 1000. Identifier generating method 1100 comprises a set of executable instructions for execution by a computer system, e.g., EDA system 1600. Identifier generating method 1100 is stored as part of instructions 1606 in memory 1604. In at least one embodiment, memory 1604 is a non-transitory computer-readable storage medium.

During execution by processor 1602, the flow begins at step 1102 where each sequential character of the cell template name 800 is determined for encoding. The flow proceeds to step 1104 and a determination is made whether all characters of the cell template name 800 have been encoded. If the determination is positive (“YES”), the flow proceeds to step 1110.

If the determination of step 1104 is negative (“NO”), the flow proceeds to step 1106. During execution of step 1106, the current character is mapped using mapping table 900 to a corresponding reference number in map column 904. The reference number is added to a corresponding sequential list of reference numbers making up the encoded cell template name 800. The flow then returns to step 1102 to continue processing.

Returning to the flow at step 1110, for each reference number in the sequential list of reference numbers a marker is created in an array (or grid), e.g., array 1000 (FIG. 10). The flow proceeds to step 1112 and a determination is made whether all reference numbers in the list have been mapped and positioned on the array. If the determination is positive (“YES”), the flow proceeds for further processing.

If the determination of step 1112 is negative (“NO”), the flow proceeds to step 1114. During execution of step 1112, the current reference number of the list is positioned on the array. The positioned is determined with respect to the reference number for the X axis and the sequential number of the reference number in the list for the Y axis. The flow then returns to step 1110 to continue processing.

After completion of execution of method 1100, the PMID such as PMID 1000 is created and includes an encoded version of the cell template name 800 using markers, e.g., marker 1002, on an array.

The PMID 1000 is added to PMID layer 500 and positioned as described.

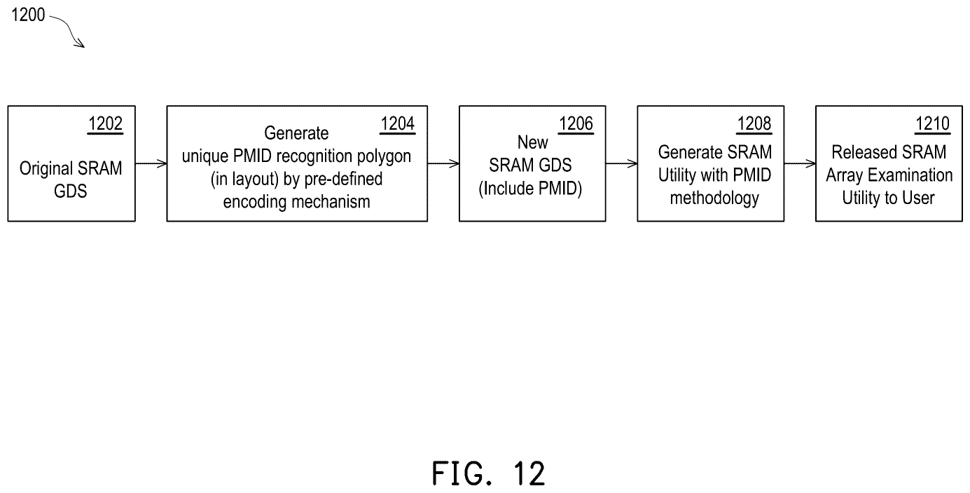

FIG. 12 is a flowchart of a method 1200 of generating a software tool with an identifier and examination utility therein, in accordance with some embodiments. The flow begins at step 1202 wherein an original graphic design system (GDS) file, usable in conjunction with EDA system 1600, is received. In an embodiment, the original GDS file includes one or more cell layout templates, e.g., SRAM memory cell layout templates, included therein. The flow proceeds to step 1204.

During execution of step 1204, EDA system 1600 generates a unique PMID 1000 using an encoding mechanism, e.g., ID encoder 220, ID generating method 1100, based on the cell template identifier for each template in the GDS file. The flow proceeds to step 1206.

During execution of step 1206, the generated PMID 1000 is added to each cell template, e.g., added to PMID layer 420, 500, and a new GDS file is generated including the revised cell templates with PMIDs. The flow proceeds to step 1208.

During execution of step 1208, a layout examination utility, e.g., an SRAM array examination utility, comprising executable instructions is generated for performing pattern matching based on the PMID 1000 in one or more cell templates. The flow proceeds to step 1210 wherein the layout examination utility is distributed for use to users, e.g., layout designers. In some embodiments, the layout examination utility is a cell layout template utility for use on cell layout templates other than SRAM memory cells.

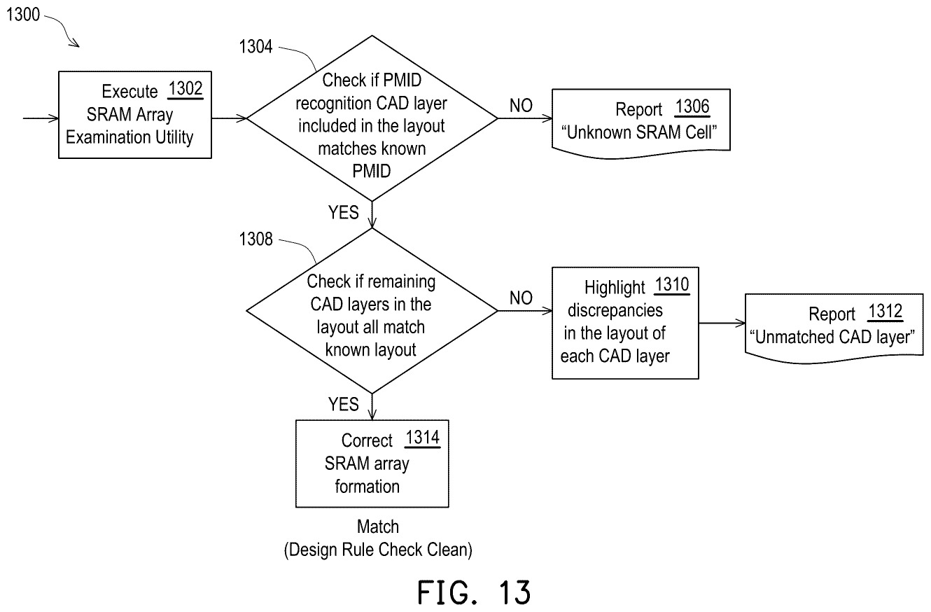

FIG. 13 is a flow chart of a method 1300 of executing a pattern match using an identifier, in accordance with some embodiments. The flow begins at step 1302 wherein the layout examination utility is initially executed, e.g., using EDA system 1600. A generated layout file is received by the layout examination utility. The flow proceeds to step 1304.

During execution of step 1304, EDA system 1600 determines whether the PMID in the PMID layer of the cell layout in the generated layout file matches a known PMID, e.g., stored in standard cell library 1607 or a list of known PMIDs of cell layouts stored in memory 1604. In at least some embodiments, EDA system 1600 performs an optical inspection of the PMID layer, e.g., PMID layer 420, to identify at least one PMID in the layer. In at least one embodiment, EDA system 1600 performs an automatic identification and data capture technique, e.g., an optical character recognition, a barcode or QR scan, or the like on the PMID. In at least one embodiment, after reading a PMID from the cell under examination, EDA system 1600 decodes the encoded unique identifier from the PMID to obtain the unique cell layout template identifier. The unique cell layout template identifier is then used to identify the corresponding cell layout template in a data store of known cell layout templates. In at least some embodiments, if more than one PMID are present in the PMID layer, the examination utility compares each PMID with known PMIDs of known cell layout templates to identify one or more corresponding known cell layout templates. In at least some embodiments, EDA system 1600 performs a geometry-based comparison between a PMID, e.g., PMID 600, found in a PMID layer of the cell layout under examination and a PMID of a known cell layout template in, for example, a data store of known cell layout templates. In response to a positive (“YES”) determination, the flow proceeds to step 1308.

Responsive to a negative (“NO”) determination, the flow proceeds to step 1306. During execution of step 1306, EDA system 1600 generates a notification that an unknown cell layout has been identified. In some embodiments, the notification includes display of the notification on a display, e.g., I/O 1610, storage of the notification in memory 1604, or the like. In some embodiments, the notification identifies the location of the unknown cell layout within the layout GDS file. In at least one embodiment, if the cell layout either does not include the PMID layer or includes the PMID layer but the cell layout does not match the identified layout, the flow proceeds to step 1306.

Returning to the flow at step 1308, EDA system 1600 has identified a match between a PMID on a cell layout template of the provided GDS file and a known PMID. EDA system 1600 then compares the layout of the remaining layers, e.g., layers 402-414, of the cell layout from the GDS file with the layers of the known PMID. That is, according to an embodiment, the EDA system 1600 compares a user supplied cell layout with the corresponding cell layout template on which the user supplied cell layout is based. In response to the EDA system 1600 determining that the remaining layers match the known cell layout template, the flow proceeds to step 1314.

Responsive to the EDA system 1600 determining that at least one of the remaining layers does not match the known cell layout template, the flow proceeds to step 1310. During execution of step 1310, EDA system 1600 highlights discrepancies in the layout between the user supplied cell layout and the known cell layout template. In at least one embodiment, EDA system 1600 highlights discrepancies by generating a comparison markup file graphically and/or textually indicating discrepancies therein. The flow proceeds to step 1312.

During execution of step 1312, EDA system 1600 generates a notification that an unmatched layer of the cell layout has been identified. In some embodiments, the notification includes display of the notification on a display, e.g., I/O 1610, storage of the notification in memory 1604, or the like. In some embodiments, the notification includes the comparison markup file to identify the location of the unknown cell layout within the layout GDS file.

Returning to the flow at step 1314, EDA system 1600 determines that the cells in the cell layout match the cells in the cell layout template. In at least one embodiment, responsive to the determination that the cells in the cell layout match the cells in the cell layout template, EDA system 1600 generates a notification that the cells match the cell layout.

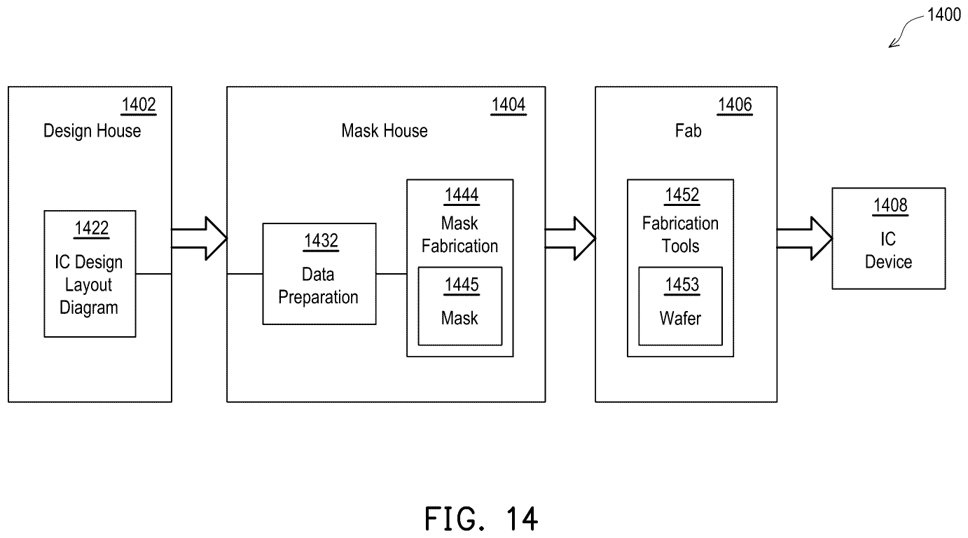

FIG. 14 is a block diagram of an integrated circuit (IC) manufacturing system 1400, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1402, a mask house 1404, and an IC manufacturer/fabricator (fab) 1406, that interact with one another in the design, development, and manufacturing cycles and/or services related to manufacturing an IC device 1408. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1402, mask house 1404, and IC fab 1406 is owned by a single larger company. In some embodiments, two or more of design house 1402, mask house 1404, and IC fab 1406 coexist in a common facility and use common resources.

Design house (or design team) 1402 generates an IC design layout diagram 1422. IC design layout diagram 1422 includes various geometrical patterns designed for an IC device 1408. The geometrical patterns correspond to patterns of metal, oxide, or semiconductor layers that make up the various components of IC device 1408 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1402 implements a proper design procedure to form IC design layout diagram 1422. The design procedure includes one or more of logic design, physical design or place and route. IC design layout diagram 1422 is presented in one or more data files having information of the geometrical patterns. For example, IC design layout diagram 1422 can be expressed in a GDSII file format or DFII file format.

Mask house 1404 includes data preparation 1432 and mask fabrication 1444. Mask house 1404 uses IC design layout diagram 1422 to manufacture one or more masks 1445 to be used for fabricating the various layers of IC device 1408 according to IC design layout diagram 1422. Mask house 1404 performs mask data preparation 1432, where IC design layout diagram 1422 is translated into a representative data file (RDF). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout diagram 1422 is manipulated by mask data preparation 1432 to comply with particular characteristics of the mask writer and/or requirements of IC fab 1406. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for photolithographic implementation effects during mask fabrication 1444, which may undo part of the modifications performed by OPC in order to meet mask creation rules.

In some embodiments, mask data preparation 1432 includes lithography process checking (LPC) that simulates processing that will be implemented by IC fab 1406 to fabricate IC device 1408. LPC simulates this processing based on IC design layout diagram 1422 to create a simulated manufactured device, such as IC device 1408. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purposes of clarity. In some embodiments, data preparation 1432 includes additional features such as a logic operation (LOP) to modify the IC design layout diagram 1422 according to manufacturing rules. Additionally, the processes applied to IC design layout diagram 1422 during data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1406 is an IC fabrication business that includes one or more manufacturing facilities for the fabrication of a variety of different IC products. In some embodiments, IC Fab 1406 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1406 includes fabrication tools 1452 configured to execute various manufacturing operations on semiconductor wafer 1453 such that IC device 1408 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1406 uses mask(s) 1445 fabricated by mask house 1404 to fabricate IC device 1408. Thus, IC fab 1406 at least indirectly uses IC design layout diagram 1422 to fabricate IC device 1408. In some embodiments, semiconductor wafer 1453 is fabricated by IC fab 1406 using mask(s) 1445 to form IC device 1408. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

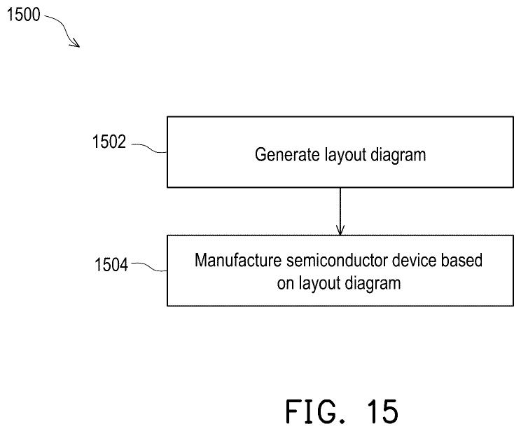

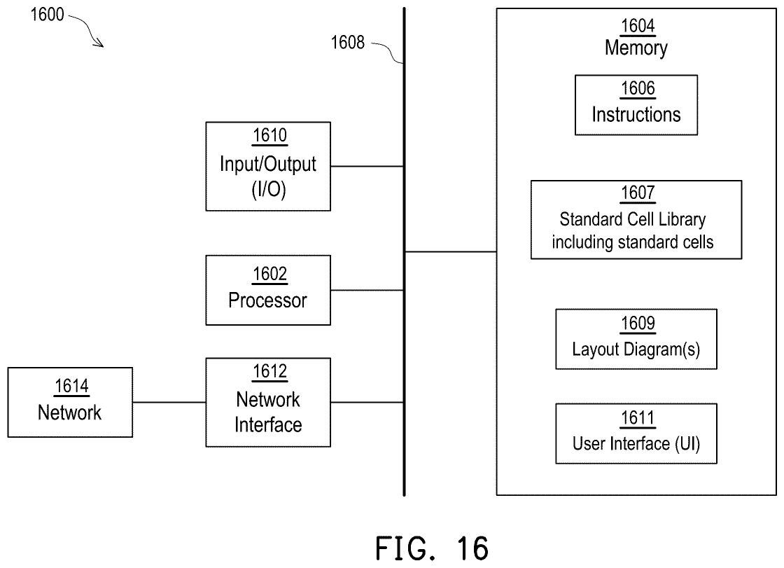

FIG. 15 is a flowchart of a method 1500 of manufacturing a semiconductor device, in accordance with some embodiments.

Method 1500 is implementable, for example, using EDA system 1600 (FIG. 16, discussed below) and an integrated circuit (IC), manufacturing system 1400 (FIG. 14, discussed above), in accordance with some embodiments. Examples of a semiconductor device which can be manufactured according to method 1500 include semiconductor device 400 of FIG. 4, or the like.

In FIG. 15, method 1500 includes blocks 1502-1504. At block 1502, a layout diagram is generated which, among other things, includes one or more of layout diagrams disclosed herein, or the like. Block 1502 is implementable, for example, using EDA system 1400 (FIG. 14, discussed above), in accordance with some embodiments.

More particularly, block 1502 includes generating shapes corresponding to structures in a semiconductor diagram which are to be represented. For example, regarding at block 1502: where the layout diagram being generated corresponds to a cell region, block 1502 includes generating shapes corresponding to the structures in the cell region. From block 1502, flow proceeds to block 1504.

At block 1504, based on the layout diagram, at least one of (A) one or more photolithographic exposures are made or (B) one or more semiconductor masks are fabricated or (C) one or more components in a layer of a semiconductor device are fabricated. See discussion above of FIG. 14.

FIG. 16 is a block diagram of an electronic design automation (EDA) system 1600 in accordance with some embodiments.

In some embodiments, EDA system 1600 includes an automatic placement and routing (APR) system. Methods described herein of designing layout diagrams represent wire routing arrangements, in accordance with one or more embodiments, are implementable, for example, using EDA system 1600, in accordance with some embodiments.

In some embodiments, EDA system 1600 is a general purpose computing device including a hardware processor 1602 and a non-transitory, computer-readable storage medium 1604. Storage medium 1604, amongst other things, is encoded with, i.e., stores, computer program code 1606, i.e., a set of executable instructions. Execution of instructions 1606 by hardware processor 1602 represents (at least in part) an EDA tool which implements a portion or all of the methods described herein in accordance with one or more embodiments (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute computer program code 1606 encoded in computer-readable storage medium 1604 in order to cause system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, storage medium 1604 stores computer program code 1606 configured to cause system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods. In one or more embodiments, storage medium 1604 stores library 1607 of standard cells including such standard cells or cell layout templates as disclosed herein. In one or more embodiments, storage medium 1604 stores one or more layout diagrams 1609 corresponding to one or more layouts disclosed herein.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1600.

System 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a UI through I/O interface 1610. The information is stored in computer-readable medium 1604 as user interface (UI) 1611.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1600. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

In some embodiments, a method of generating a pattern match identifier (PMID) comprises receiving a first cell layout design, the first cell layout design having one or more layers; generating a PMID for the first cell layout design using a predefined encoding, the PMID based on an attribute of the first cell layout design; and generating a second cell layout design based on the first cell layout design and the PMID, the PMID being stored in a layer of the second cell layout design. In some embodiments, the PMID is on a top layer of the second cell layout design. In some embodiments, the predefined encoding comprises a mapping table correlating a unique number for each character in the attribute of the first cell layout design. In some embodiments, wherein the first cell layout design is a cell template and the attribute is the name of the cell template. In some embodiments, wherein the PMID is stored in each corner of the second cell layout design. In some embodiments, wherein each corner PMID is a mirror image of the PMID on a connected edge of the second cell layout design. In some embodiments, wherein the PMID comprises an array of one or more markers, each marker in a corresponding row and column of the array, the number of rows corresponding to the number of unique numbers in the mapping table, the number of columns corresponding to the number of characters in the attribute, the method further comprises: placing a marker at a row and column intersection corresponding to the encoded attribute. In some embodiments, the marker is at least one of a polygon, line, dot, or circle. In some embodiments, the generating a second cell layout design comprises adding the PMID to a layer of the first cell layout design. In some embodiments, the predefined encoding comprises hashing the attribute of the first cell layout design. In some embodiments, the PMID is at least one of a QR code or a barcode of the attribute of the first cell layout design.

In some embodiments, a system for generating cell layout designs having a pattern match identifier (PMID) comprises a template identifier generator configured to create a unique identifier for a cell layout design; an encoder configured to encode the unique identifier for the cell layout design using a predefined encoding into a PMID; and a template updater configured to add the PMID to the cell layout design. In some embodiments, the unique identifier is at least one of a name of the cell layout design or a serial number of the cell layout design. In some embodiments, the encoder comprises at least one of a mapping table, a QR encoder, a barcode encoder, a hashing function, or a text formatter. In some embodiments, the PMID comprises an array of markers and the template updater is configured to add at least one array corresponding to the PMID to a layer of the cell layout design. In some embodiments, the template updater is configured to add the at least one array to a topmost layer of the cell layout design.

In some embodiments, a method of identifying cell layout designs comprises executing a cell layout design examination utility on a layout file; determining if a pattern match identifier (PMID) in a layer of a cell layout of the layout file matches a known PMID of a known cell layout; responsive to a determination of a mismatch between the PMID of the cell layout and a known PMID of a known cell layout, generating a notification that the cell layout is unknown; responsive to a determination of a match between the PMID of the cell layout and a known PMID of a known cell layout, determining if remaining layers of the cell layout match corresponding layers of the known cell layout; and responsive to a determination of a mismatch between the remaining layers of the cell layout and the known cell layout, generating a notification that at least one layer of the remaining layers of the cell layout do not match the corresponding layer of the known cell layout. In some embodiments, the generating a notification that at least one layer of the remaining layers of the cell layout do not match the corresponding layer of the known cell layout further comprises, identifying the discrepancies between the cell layout and the known cell layout. In some embodiments, the method further comprises responsive to a determination of a match between the remaining layers of the cell layout and the known cell layout, generating a notification that the cell layout matches the known cell layout. In some embodiments, the method further comprises generating a comparison markup file of the cell layout indicating the location of the discrepancies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of generating a pattern match identifier (PMID), the method comprising:
receiving a first cell layout design, the first cell layout design having one or more layers;
generating a PMID for the first cell layout design using a predefined encoding, the PMID based on an attribute of the first cell layout design; and
generating a second cell layout design based on the first cell layout design and the PMID, the PMID being stored in a layer of the second cell layout design.

2. The method of claim 1, wherein the PMID is on a top layer of the second cell layout design.

3. The method of claim 1, wherein the predefined encoding comprises a mapping table correlating a unique number for each character in the attribute of the first cell layout design.

4. The method of claim 1, wherein the first cell layout design is a cell template and the attribute is the name of the cell template.

5. The method of claim 1, wherein the PMID is stored in each corner of the second cell layout design.

6. The method of claim 5, wherein each corner PMID is a mirror image of the PMID on a connected edge of the second cell layout design.

7. The method of claim 3, wherein the PMID comprises an array of one or more markers, each marker in a corresponding row and column of the array, the number of rows corresponding to the number of unique numbers in the mapping table, the number of columns corresponding to the number of characters in the attribute, the method further comprising:
placing a marker at a row and column intersection corresponding to the encoded attribute.

8. The method of claim 7, wherein the marker is at least one of a polygon, line, dot, or circle.

9. The method of claim 1, wherein the generating a second cell layout design comprises adding the PMID to a layer of the first cell layout design.

10. The method of claim 1, wherein the predefined encoding comprises hashing the attribute of the first cell layout design.

11. The method of claim 3, wherein the PMID is at least one of a QR code or a barcode of the attribute of the first cell layout design.

12. A system for generating cell layout designs having a pattern match identifier (PMID), comprising:
a template identifier generator configured to create a unique identifier for a cell layout design;
an encoder configured to encode the unique identifier for the cell layout design using a predefined encoding into a PMID; and
a template updater configured to add the PMID to the cell layout design.

13. The system of claim 12, wherein the unique identifier is at least one of a name of the cell layout design or a serial number of the cell layout design.

14. The system of claim 12, wherein the encoder comprises at least one of a mapping table, a QR encoder, a barcode encoder, a hashing function, or a text formatter.

15. The system of claim 12, wherein the PMID comprises an array of markers and the template updater is configured to add at least one array corresponding to the PMID to a layer of the cell layout design.

16. The system of claim 15, wherein the template updater is configured to add the at least one array to a topmost layer of the cell layout design.

17. A method of identifying cell layout designs, comprising:
executing a cell layout design examination utility on a layout file;
determining if a pattern match identifier (PMID) in a layer of a cell layout of the layout file matches a known PMID of a known cell layout;
responsive to a determination of a mismatch between the PMID of the cell layout and the known PMID of a known cell layout, generating a notification that the cell layout is unknown;
responsive to a determination of a match between the PMID of the cell layout and a known PMID of a known cell layout, determining if remaining layers of the cell layout match corresponding layers of the known cell layout; and
responsive to a determination of a mismatch between the remaining layers of the cell layout and the known cell layout, generating a notification that at least one layer of the remaining layers of the cell layout do not match the corresponding layer of the known cell layout.

18. The method of claim 17, wherein the generating a notification that at least one layer of the remaining layers of the cell layout do not match the corresponding layer of the known cell layout further comprises, identifying the discrepancies between the cell layout and the known cell layout.

19. The method of claim 17, further comprising:
responsive to a determination of a match between the remaining layers of the cell layout and the known cell layout, generating a notification that the cell layout matches the known cell layout.

20. The method of claim 18, further comprising:
generating a comparison markup file of the cell layout indicating the location of the discrepancies.
